(19) United States
(12) Patent Application Publication
(10) Pub. No.: US 2026/0302822 A1
(43) Pub. Date: Oct. 1, 2026

(54) RAPID CHARGING APPARATUS AND METHOD FOR LITHIUM-ION BATTERY

(71) Applicants: Hyundai Motor Company, Seoul (KR); Kia Corporation, Seoul (KR); SEOUL NATIONAL UNIVERSITY R&DB FOUNDATION, Seoul (KR)

(72) Inventors: Eungju LEE, Hwaseong-Si (KR); Sanghun LEE, Hwaseong-Si (KR); SEUNG-MIN OH, Hwaseong-Si (KR); Chaelin LEE, Seoul (KR); Junhyung KIM, Seoul (KR); Ki Suk KANG, Seoul (KR)

(21) Appl. No.: 19/297,367

(22) Filed: Aug. 12, 2025

(30) Foreign Application Priority Data
Mar. 25, 2025 (KR) 10-2025-0038050

(51) Int. Cl. H02J 7/90; H01M 10/0525; H01M 10/44; H02J 7/80

(52) U.S. Cl. CPC H02J 7/933; H01M 10/0525; H01M 10/44; H02J 7/80

(57) ABSTRACT

The present disclosure relates to an apparatus and method for rapidly charging a lithium-ion battery. An apparatus for charging a lithium-ion battery according to one example may include a charging graph generation unit configured to generate a three-dimensional (3D) contour plot that represents a boundary at which lithium plating begins to occur, based on relationships among charging variables of the lithium-ion battery, the boundary being formed as a boundary surface in the 3D contour plot, and a charging current determination unit configured to determine a maximum current rate (C-rate) for charging the lithium-ion battery based on the boundary surface represented in the 3D contour plot.

### CROSS-REFERENCE TO RELATED APPLICATION

This application claims priority to Korean Patent Application No. 10-2025-0038050, filed Mar. 25, 2025, the entire disclosure of which is incorporated herein by reference.

### FIELD

The present disclosure relates to a rapid charging apparatus and method for a lithium-ion battery, and more particularly, to a rapid charging apparatus and method for a lithium-ion battery that performs rapid charging by taking into account relationships among charging variables of the lithium-ion battery.

### BACKGROUND

Graphite-based negative electrode materials may be used in lithium-ion batteries. The charging of a lithium-ion battery involves lithium ions being intercalated into a negative electrode through an electrolyte from a positive electrode. The negative electrode composed of graphite is characterized by having a low reduction potential (e.g., approximately 0.1 V vs. Li/Li⁺) and a low bulk solid diffusivity.

Under extreme conditions, such as during rapid charging of the lithium-ion battery, a large overpotential may be generated due to kinetic limitations.

Based on a potential of the negative electrode reaching a lithium reduction potential, lithium ions may be deposited on a surface of the negative electrode in the form of lithium metal, a phenomenon referred to as lithium plating (Li-plating).

Lithium plating may occur based on lithium ions failing to properly intercalate into the negative electrode, thereby degrading performance of the lithium-ion battery.

In particular, the lithium plating on the surface of the negative electrode may trigger side reactions with the electrolyte and lead to formation of a thickened solid electrolyte interphase (SEI) layer, which increases the overall resistance of a battery cell and accelerates degradation of the lithium-ion battery.

Moreover, the lithium plating formed on the surface of the negative electrode may lose electrical contact with the negative electrode during repeated charge and discharge cycles, thereby reducing an amount of lithium available for redox reactions within the lithium-ion battery.

The matters described in this Background section are only for enhancement of understanding of the background of the disclosure, and should not be taken as acknowledgement that they correspond to prior art already known to those skilled in the art.

### SUMMARY

The following summary presents a simplified summary of certain features. The summary is not an extensive overview and is not intended to identify key or critical elements.

In one aspect, an apparatus for charging a lithium-ion battery comprises:
a memory storing at least one instruction; and
a processor configured to execute the at least one instruction, wherein the at least one instruction, executed by the processor, is configured to cause the apparatus to:
   control at least one sensor associated with the lithium-ion battery to detect charging variables of the lithium-ion battery;
   generate a three-dimensional (3D) contour plot that represents a boundary at which lithium plating begins to occur, based on relationships among the charging variables of the lithium-ion battery, wherein the boundary is formed as a boundary surface in the 3D contour plot;
   determine, based on the boundary surface represented in the 3D contour plot, a maximum current rate (C-rate) for charging the lithium-ion battery; and
   control, based on the maximum C-rate, the charger to charge the battery.

In another aspect, a method is provided for charging a lithium-ion battery performed by an apparatus for charging a lithium-ion battery. The method comprises:
detecting, by controlling at least one sensor associated with the lithium-ion battery, charging variables of the lithium-ion battery;
generating a three-dimensional (3D) contour plot that represents a boundary at which lithium plating begins to occur, based on relationships among the charging variables of the lithium-ion battery, wherein the boundary being is formed as a boundary surface in the 3D contour plot; and
determining, based on the boundary surface represented in the 3D contour plot, a maximum current rate (C-rate) for charging the lithium-ion battery based on the boundary surface represented in the 3D contour plot; and
control, based on the maximum C-rate, charging of the lithium-ion battery.

In another aspect, a charging apparatus comprises:
a charger configured to charge a battery;
at least one sensor to detect sensing data associated with charging variables of the battery;
a memory storing at least one instruction; and
a processor configured to execute the at least one instruction, wherein the at least one instruction, executed by the processor, is configured to cause the charging apparatus to:
   receive, from the at least one sensor, the sensing data;
   generate a three-dimensional (3D) contour plot that represents a boundary associated with electrode degradation, based on relationships among the charging variables of the battery, wherein the boundary is formed as a boundary surface in the 3D contour plot;
   determine, based on the boundary surface represented in the 3D contour plot, a maximum current rate (C-rate) for charging the battery; and
   controlling, based on the maximum C-rate, charging of the lithium-ion battery.

In another aspect, an apparatus for charging a lithium-ion battery includes a charging graph generation unit configured to generate a three-dimensional (3D) contour plot that represents a boundary at which lithium plating begins to occur, based on relationships among charging variables of the lithium-ion battery, the boundary being formed as a boundary surface in the 3D contour plot, and a charging current determination unit configured to determine a maximum current rate (C-rate) for charging the lithium-ion battery based on the boundary surface represented in the 3D contour plot.

The apparatus may further include a battery charging unit configured to charge the lithium-ion battery at or below the maximum C-rate.

The charging graph generation unit may be configured to determine an SoC value at which the lithium plating begins to occur, based on a Coulombic efficiency determined through an SoC sweep method in which charge-discharge cycles are repeatedly performed based on a predetermined C-rate and a predetermined SoC value under constant operating temperature conditions.

The SoC sweep method may involve, under constant operating temperature conditions, charge-discharge cycles which are repeatedly performed at a C-rate to be analyzed, while an SoC value for charging is gradually increased in each cycle and discharging in each cycle is performed at a constant C-rate that is set lower than the C-rate to be analyzed.

The charging graph generation unit may be configured to set a defined Coulombic efficiency, which is consistently and repeatedly measured during repeated charge-discharge cycles in the SoC sweep method, as a reference Coulombic efficiency, and determine an amount of irreversible lithium plating occurring in each cycle based on a difference between the reference Coulombic efficiency and the Coulombic efficiency measured in each cycle.

The charging graph generation unit may be configured to determine, as an onset point of lithium plating, a point at which the amount of irreversible lithium plating reaches a predetermined ratio, and generate the 3D contour plot by plotting, on a three-dimensional graph, an SoC value corresponding to the onset point of lithium plating for each operating temperature and C-rate.

In yet another aspect, a method for rapidly charging a lithium-ion battery includes generating a three-dimensional (3D) contour plot that represents a boundary at which lithium plating begins to occur, based on relationships among charging variables of the lithium-ion battery, the boundary being formed as a boundary surface in the 3D contour plot, and determining a maximum current rate (C-rate) for charging the lithium-ion battery based on the boundary surface represented in the 3D contour plot.

The method may further include charging the lithium-ion battery at or below the maximum C-rate.

The generating the 3D contour plot may include determining an SoC value at which the lithium plating begins to occur, based on a Coulombic efficiency determined through an SoC sweep method in which charge-discharge cycles are repeatedly performed based on a predetermined C-rate and a predetermined SoC value under constant operating temperature conditions.

The SoC sweep method may be a method in which, under constant operating temperature conditions, charge-discharge cycles are repeatedly performed at a C-rate to be analyzed, while an SoC value for charging is gradually increased in each cycle and discharging in each cycle is performed at a constant C-rate that is set lower than the C-rate to be analyzed.

Generating the 3D contour plot may include setting a defined Coulombic efficiency, which is consistently and repeatedly measured during repeated charge-discharge cycles in the SoC sweep method, as a reference Coulombic efficiency, and determining an amount of irreversible lithium plating occurring in each cycle based on a difference between the reference Coulombic efficiency and the Coulombic efficiency measured in each cycle.

Generating the 3D contour plot may include determining, as an onset point of lithium plating, a point at which the amount of irreversible lithium plating reaches a predetermined ratio, and completing the 3D contour plot by plotting, on a three-dimensional graph, an SoC value corresponding to the onset point of lithium plating for each operating temperature and C-rate.

In some examples, a 3D contour plot may be generated to represent a boundary at which lithium plating begins to occur, based on relationships among charging variables of a lithium-ion battery. Accordingly, based on a 3D contour plot generated for a single cell system, a rapid charging strategy that considers various charging variables may be developed.

In some examples, a lithium-ion battery may be rapidly charged at a maximum current rate (C-rate) at which lithium plating does not occur. Accordingly, while maintaining the same target charging time as in existing rapid charging, the influence of lithium plating may be reduced, and thus side reactions and degradation caused by the lithium plating may be suppressed and alleviated.

Aspects of the present disclosure are not limited to those mentioned above, and other aspects and advantages not mentioned above will be understood from the following description, and become more apparent from the exemplary embodiments. Moreover, aspects of the present disclosure may be realized by the means and combinations thereof indicated in claims.

### BRIEF DESCRIPTION OF THE DRAWINGS

The foregoing and other aspects, features, and advantages, as well as the following detailed description of the embodiments, will be better understood when read in conjunction with the accompanying drawings. However, the present disclosure is not intended to be limited to the details shown in the drawings, and various modifications and structural changes may be made therein without departing from the spirit of the present disclosure and within the scope and range of equivalents of the claims. Like reference numbers and designations in the various drawings indicate like elements.

FIG. 1 is a diagram illustrating a 3D contour plot according to one example.

FIG. 2 is a diagram illustrating a configuration of a rapid charging apparatus for a lithium-ion battery according to one example.

FIG. 3 is a graph illustrating a state of charge (SoC) sweep method protocol according to one example.

FIG. 4 is a graph illustrating charge and discharge curves of an SoC sweep method protocol according to one example.

FIG. 5 is a graph illustrating Coulombic efficiency according to one example.

FIG. 6 is a graph illustrating irreversible lithium plating according to one example.

FIG. 7 is a graph illustrating a region in which lithium plating does not occur in a 3D contour plot according to one example.

FIG. 8 is a graph illustrating a charging protocol based on a maximum C-rate according to one example.

FIG. 9 is a graph illustrating an example of actual charging.

FIG. 10 is a graph illustrating a performance of an existing constant current (CC) protocol.

FIG. 11 is a graph illustrating a performance of an optimized protocol for charging at a maximum C-rate according to one example.

FIG. 12 is a flowchart illustrating a rapid charging method for a lithium-ion battery according to one example.

FIG. 13 shows an example computing system.

### DETAILED DESCRIPTION

Hereinafter, examples disclosed in the present specification will be described in detail with reference to the accompanying drawings. However, the following embodiments are provided merely as references for describing the present disclosure in detail, and the present disclosure is not limited thereto and may be implemented in various forms.

Unless otherwise defined, all technical and scientific terms used in the present disclosure have the same meanings as commonly understood by those skilled in the art of this application. The terms "include," "comprise," or “have” indicate the presence of features, numbers, steps, operations, components, parts, or combinations thereof described in the specification, but do not exclude in advance any of the features, numbers, steps, operations, components, parts, or combinations thereof.

A singular expression used herein may include the meaning of the plural unless otherwise stated in the context, which also applies to the singular expression described in the claims.

Certain embodiments disclosed in the present document will be described in detail with reference to the accompanying drawings. Like reference numerals designate like elements, and redundant descriptions thereof will be omitted. Further, such as "module" and a "unit," suffixes for components used in the following description are given or mixed and used by considering easiness in preparing a specification and do not have a meaning or role distinguished from each other in themselves. In addition, in describing an embodiment disclosed in the present document, if it is determined that a detailed description of a related art incorporated herein unnecessarily obscure the gist of the embodiment, the detailed description thereof will be omitted. Furthermore, it should be understood that the appended drawings are intended only to help understand embodiments disclosed in the present document and do not limit the technical principles and scope of the present disclosure; rather, it should be understood that the appended drawings include all of the modifications, equivalents or substitutes described by the technical principles and belonging to the technical scope of the present disclosure.

Although the terms first, second, and the like, may be used herein to describe various elements, these elements should not be limited by these terms. These terms are generally only used to distinguish one element from another.

When an element or layer is referred to as being "on," "engaged to," "connected to," or "coupled to" another element or layer, it may be directly on, engaged, connected, or coupled to the other element or layer, or intervening elements or layers may be present. In contrast, when an element is referred to as being "directly on," "directly engaged to," "directly connected to," or "directly coupled to" another element or layer, there may be no intervening elements or layers present.

When a component, unit, device, element, apparatus, or the like of the present disclosure is described as having a purpose or performing an operation, function, or the like, the component, unit, device, element, apparatus, or the like should be considered herein as being “configured to” meet that purpose or to perform that operation or function. Each component, unit, device, element, apparatus, and the like may separately embody or be included with a processor and a memory, such as a non-transitory computer readable media, as part of the apparatus.

The term “unit” or “module” used in this specification signifies one unit that processes at least one function or operation, and may be realized by hardware, software, or a combination thereof. The operations of the method or the functions described in connection with the forms disclosed herein may be embodied directly in a hardware or a software module executed by a processor, or in a combination thereof.

For purposes of this application and the claims, using the exemplary phrase "at least one of: A; B; or C" or "at least one of A, B, or C," the phrase means "at least one A, or at least one B, or at least one C, or any combination of at least one A, at least one B, and at least one C. Further, exemplary phrases, such as "A, B, and C", "A, B, or C", "at least one of A, B, and C", "at least one of A, B, or C", etc. as used herein may mean each listed item or all possible combinations of the listed items. For example, "at least one of A or B" may refer to (1) at least one A; (2) at least one B; or (3) at least one A and at least one B.

The expression "based on" as used herein is intended to describe one or more factors that influence an act or operation of determining or deciding described in a phrase or sentence including that expression, and this expression does not exclude any additional factors that influence the act or operation of determining or deciding.

The term “module” or “unit” used in the specification means a software and/or hardware component, and the “module” or “unit” performs certain operations/functions/roles. However, the “module” or “unit” is not construed as being limited to software or hardware. The “module” or “unit” may be configured to be in an addressable storage medium or to execute one or more processors. Therefore, as an example, the “module” or “unit” may include at least one of components such as software components, object-oriented software components, class components, and task components, processes, functions, attributes, procedures, sub-routines, segments of program codes, drivers, firmware, micro-codes, circuits, data, databases, data structures, tables, arrays, or variables. Functions provided in the components, “modules”, or “units” may be combined into a smaller number of components, “modules”, or “units” or further divided into additional components, “modules”, or “units”.

In the present disclosure, the “module” or “unit” may be realized as a processor and a memory. The “processor” should be widely construed to include a general-purpose processor, a central processing unit (CPU), a microprocessor, a digital signal processor (DSP), a microcontroller, a state machine, or the like. In some environments, the “processor” may refer to an application-specific integrated circuit (ASIC), a programmable logic device (PLD), or a field-programmable gate array (FPGA), and the like. For example, the “processor” may refer to a combination of processing devices such as a combination of a DSP and a microprocessor, a combination of a plurality of microprocessors, a combination of one or more microprocessors combined with a DSP core, or any other such combination. Moreover, the “memory” should be widely construed to include any electronic component capable of storing electronic information. The “memory” may refer to various types of processor-readable medium such as a random access memory (RAM), a read only memory (ROM), a non-volatile random access memory (NVRAM), a programmable read only memory (PROM), an erasable programmable read only memory (EPROM), an electrically erasable programmable read only memory (EEPROM), a flash memory, a magnetic or optical data storage device, and registers. When the processor can read information from a memory and/or record the information in the memory, the memory may be in a state of electronic communication with a processor. Memory integrated into a processor is in a state of electronic communication with the processor.

The one or more features described herein may be provided as a computer program stored in a computer-readable recording medium in order to be executed on a computer. The medium may either continuously store a computer-executable program or temporarily store the program for execution or download. Furthermore, the medium may be a variety of recording or storage means in the form of a single hardware device or multiple combined hardware devices, and is not limited to media directly connected to some computer system but may also be distributed across a network. Examples of such media include magnetic media such as a hard disk, a floppy disk, or a magnetic tape, optical recording media such as a CD-ROM or a DVD, magneto-optical media such as a floptical disk, and a ROM, RAM, or flash memory, among others, configured to store program instructions. Additional examples of such media include media or storage media that are managed by an app store that distributes applications or by various other sites or servers that provide or distribute software.

In a hardware implementation, processing units used for performing the techniques may be implemented within one or more ASICs, DSPs, digital signal processing devices, programmable logic devices, field-programmable gate arrays, processors, controllers, microcontrollers, microprocessors, electronic devices, or computers or combinations thereof designed to perform the functions described in the present disclosure.

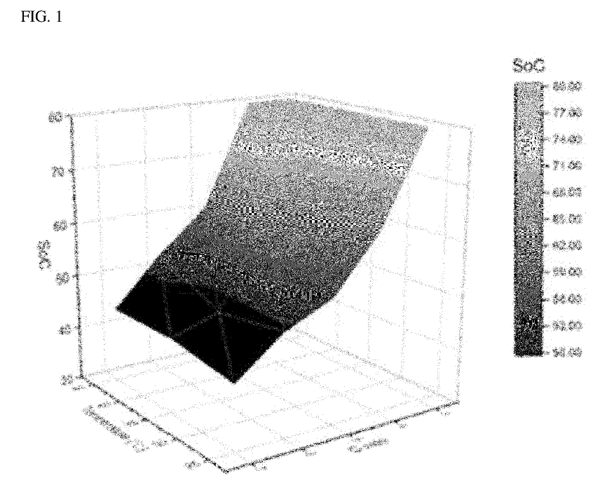

Hereinafter, a rapid charging apparatus and method for a lithium-ion battery according to embodiments of the present disclosure will be described in detail with reference to FIGS. 1 to 12.

Typically, it is difficult to achieve rapid charging in lithium-ion batteries using graphite-based electrodes due to lithium plating that occurs on the graphite electrode during rapid charging.

In some examples, a new rapid charging approach is proposed to reduce the influence of lithium plating by considering relationships among charging variables of the lithium-ion battery.

To this end, in some examples a 3D contour plot is generated to represent a boundary at which lithium plating begins to occur based on relationships among charging variables of the lithium-ion battery.

FIG. 1 is a diagram illustrating a 3D contour plot according to one or more aspects.

Referring to FIG. 1, temperature, current rate (C-rate), and state of charge (SoC) may be set as charging variables of a lithium-ion battery, and a boundary at which lithium plating begins to occur is represented in three-dimensional space. Based on the boundary, a maximum C-rate that does not cause lithium plating may be determined for each SoC.

Accordingly, the lithium-ion battery may be rapidly charged at a maximum C-rate that does not cause lithium plating. As a result, while maintaining the same target charging time as in existing rapid charging, the influence of lithium plating may be reduced, and side reactions and degradation caused by lithium plating may be suppressed and alleviated.

In particular, a 3D contour plot generated for a single cell system under various operating temperatures and C-rate conditions may be utilized to establish a rapid charging strategy for a lithium-ion battery.

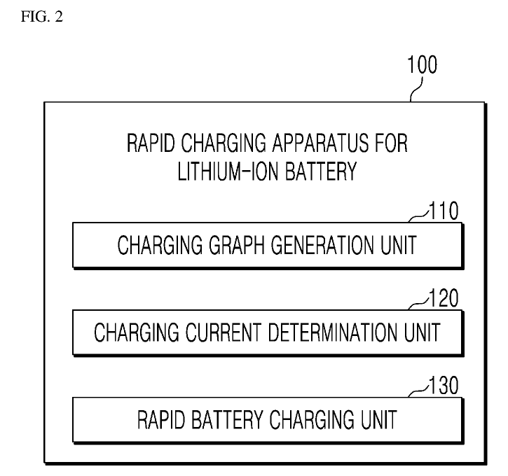

Hereinafter, a rapid charging apparatus for a lithium-ion battery according to one or more aspects will be described in detail with reference to FIGS. 2 to 11.

FIG. 2 is a diagram illustrating a configuration of a rapid charging apparatus for a lithium-ion battery.

Referring to FIG. 2, a rapid charging apparatus 100 for a lithium-ion battery may include a charging graph generation unit 110, a charging current determination unit 120, and a rapid battery charging unit 130.

The charging graph generation unit 110 may be configured to generate a 3D contour plot to represent a boundary at which lithium plating begins to occur based on relationships among charging variables of the lithium-ion battery.

Variables that may affect the occurrence of lithium plating during charging of the lithium-ion battery may include operating temperature, charging current, and state of charge (SoC). Accordingly, the charging graph generation unit 110 may set the operating temperature, C-rate, and SoC as charging variables of the lithium-ion battery.

Based on the completion of the setting of charging variables of the lithium-ion battery, the charging graph generation unit 110 may be configured to repeatedly perform charge-discharge cycles for a lithium-ion battery according to a predetermined C-rate and a predetermined SoC, under constant operating temperature conditions predetermined for analysis of a pouch cell that has completed a formation process.

In one example, an SoC sweep method may be defined as a method of repeatedly performing charge-discharge cycles for a lithium-ion battery based on a predetermined C-rate and a predetermined SoC value under constant operating temperature conditions.

That is, the charging graph generation unit 110 may be configured to determine an SoC value at which lithium plating begins to occur, based on a Coulombic efficiency determined through an SoC sweep method in which charge-discharge cycles are repeatedly performed based on a predetermined C-rate and a predetermined SoC value under constant operating temperature conditions.

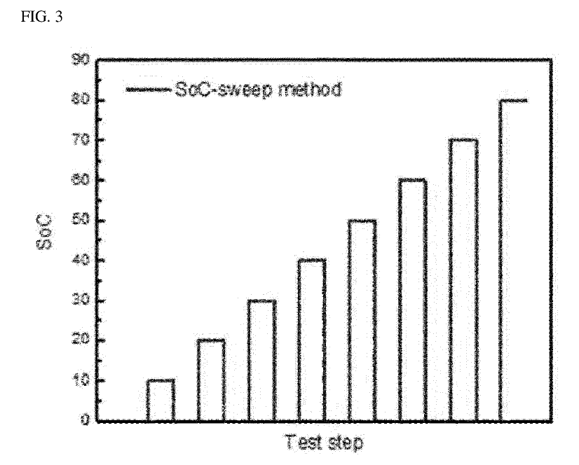

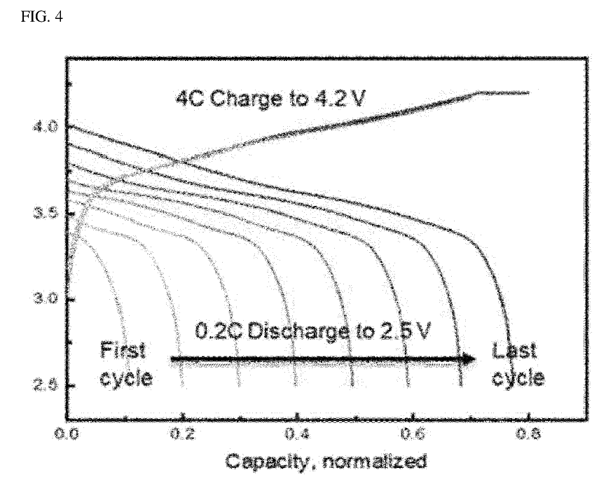

FIG. 3 is a graph illustrating an SoC sweep method protocol according to one or more aspects, and FIG. 4 is a graph illustrating charge and discharge curves of an SoC sweep method protocol according to one example.

Referring to FIGS. 3 and 4, in an SoC sweep method, under constant operating temperature conditions, charge-discharge cycles are repeatedly performed at a C-rate to be analyzed, while an SoC value for charging is gradually increased in each cycle and discharging in each cycle is performed at a constant C-rate (e.g., 0.2C) that is set lower than the C-rate to be analyzed.

The charging graph generation unit 110 may be configured to set a defined Coulombic efficiency, which is consistently and repeatedly measured during repeated charge-discharge cycles in the SoC sweep method, as a reference Coulombic efficiency, and determine an amount of irreversible lithium plating occurring in each cycle based on a difference between the reference Coulombic efficiency and the Coulombic efficiency measured in each cycle.

The charging graph generation unit 110 may be configured to determine the amount of irreversible lithium plating by multiplying the difference between the reference Coulombic efficiency and the Coulombic efficiency measured in each cycle by the SoC value for each cycle.

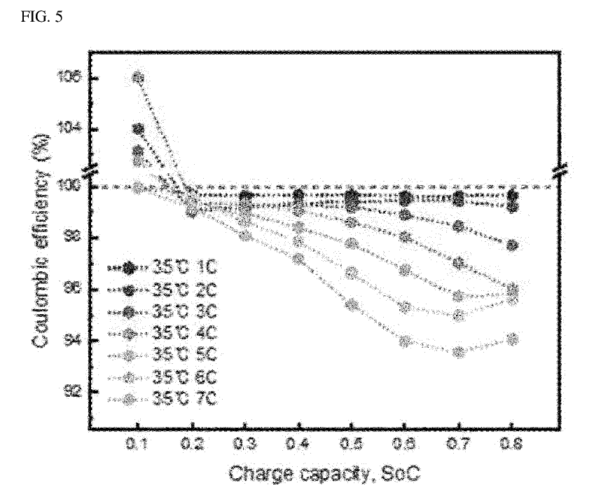

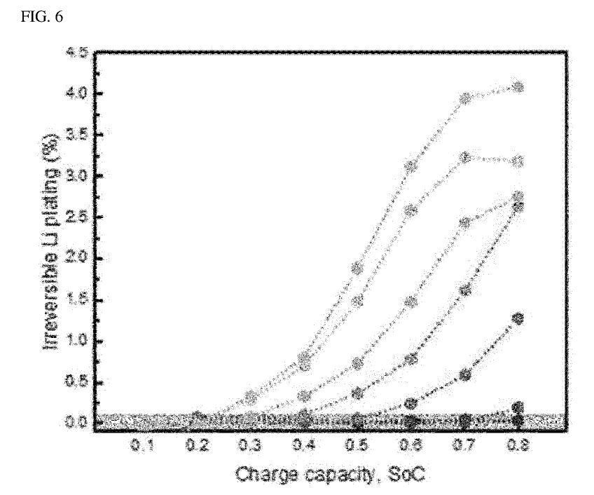

FIG. 5 is a graph illustrating Coulombic efficiency and FIG. 6 is a graph illustrating irreversible lithium plating according to one or more aspects.

Referring to FIGS. 5 and 6, the Coulombic efficiency measured in each cycle may maintain a constant value (e.g., 99.4%) and then show a decreasing trend based on high-rate charging being performed up to a high SoC range. In this case, a consistently and repeatedly measured Coulombic efficiency may be set as a reference Coulombic efficiency, and an amount of irreversible lithium plating may be determined by multiplying the difference between the reference Coulombic efficiency and the Coulombic efficiency measured in each cycle by a charge capacity.

It should be noted that the reference Coulombic efficiency is not 100% because time-dependent side reactions, such as the formation of a solid electrolyte interphase (SEI) layer, inevitably occur inside the cell. This may be confirmed by the fact that the baseline value of the Coulombic efficiency decreases as the operating temperature increases.

The charging graph generation unit 110 may be configured to determine, based on the determination of the amount of irreversible lithium plating, a point at which the amount of irreversible lithium plating reaches a predetermined specific ratio (e.g., 0.05%) as an onset point of the lithium plating, and complete a 3D contour plot by plotting, on a three-dimensional graph, an SoC value corresponding to the onset point of the lithium plating for each operating temperature and C-rate.

The charging current determination unit 120 may be configured to, based on the completion of the 3D contour plot, determine a region in which the lithium plating does not occur in the completed 3D contour plot, and determine a maximum C-rate at which the lithium-ion battery may be charged without lithium plating for each SoC based on the determined region.

In this case, based on a boundary surface at which lithium plating begins to occur, the charging current determination unit 120 may be configured to determine a region in which the lithium plating does not occur in the completed 3D contour plot.

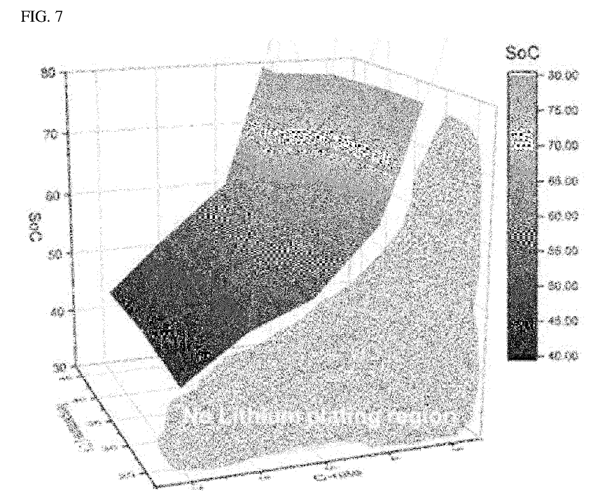

FIG. 7 is a graph illustrating a region in which lithium plating does not occur in a 3D contour plot according to one example.

Referring to FIG. 7, a 3D contour plot depicts a boundary surface representing the onset of lithium plating, using operating temperature, C-rate, and SoC as charging variables, with SoC set as the Z-axis. A region below the boundary surface may be determined as a lithium plating-safe region in which lithium plating does not occur. Accordingly, this enables implementation of a protocol for determining, for each SoC, a maximum C-rate that does not cause lithium plating.

To fully utilize the 3D contour plot in implementing the protocol for determining the maximum C-rate, an environment should be provided that is capable of rapidly adjusting not only the C-rate but also the operating temperature for each SoC.

The rapid battery charging unit 130 may be configured to rapidly charge the lithium-ion battery at a C-rate that does not exceed the maximum C-rate, based on a determination of the maximum C-rate that does not cause lithium plating for each SoC.

That is, the rapid battery charging unit 130 may be configured to rapidly charge the lithium-ion battery at the maximum C-rate within a lithium plating-safe region in which the lithium plating does not occur in the 3D contour plot.

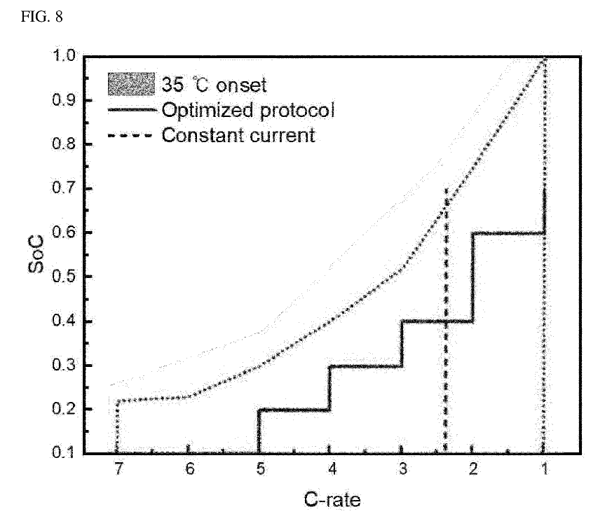

FIG. 8 is a graph illustrating a charging protocol based on a maximum C-rate according to one example.

Referring to FIG. 8, in an environment where the maximum C-rate is determined by the highest charging current that allows for the fastest charging without lithium plating, a cross-sectional view of the 3D contour plot may be observed with the operating temperature set to 35°C for convenience in reproducing the experiment. In this view, the solid line represents an optimized protocol for charging at the maximum C-rate within the lithium plating-safe region, and the dotted line represents a corresponding constant current (CC) protocol.

As may be seen, according to one example, following an optimized charging protocol that applies the maximum C-rate within the lithium plating-safe region may enable reduction of lithium plating compared to existing methods with the same charging time, thereby suppressing or mitigating resulting side reactions and degradation.

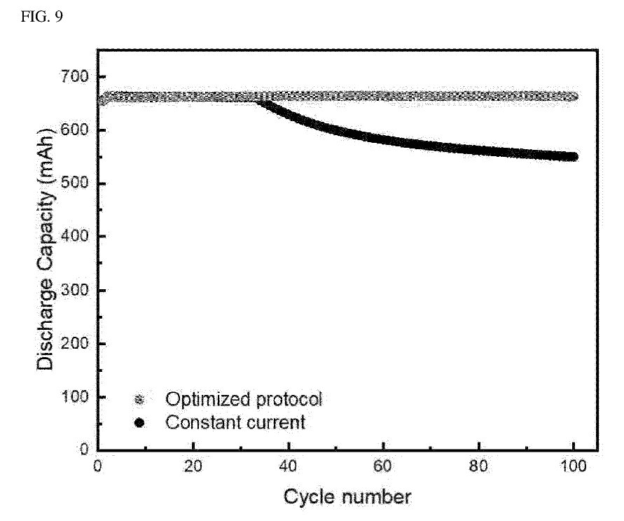

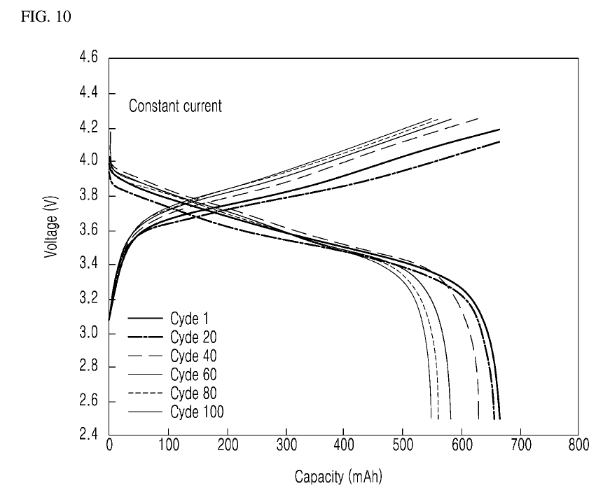

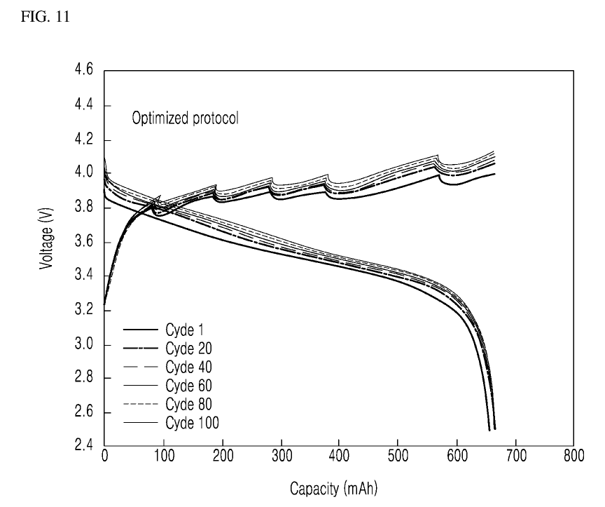

FIG. 9 is a graph illustrating an example of actual charging; FIG. 10 is a graph illustrating a performance of an existing constant current (CC) protocol; and FIG. 11 is a graph illustrating a performance of an optimized protocol for charging at a maximum C-rate according to one example.

Referring to FIG. 9, it may be seen that a cycle life is improved in the optimized protocol, which uses the 3D contour plot and takes 17.7 minutes to charge from 0% to 70% SoC, compared to the CC protocol. In addition, referring to FIGS. 10 and 11, it may be seen from the charge/discharge voltage curves that an increase in potential during charging due to degradation is more suppressed in the optimized protocol using the 3D contour plot, compared to the CC protocol.

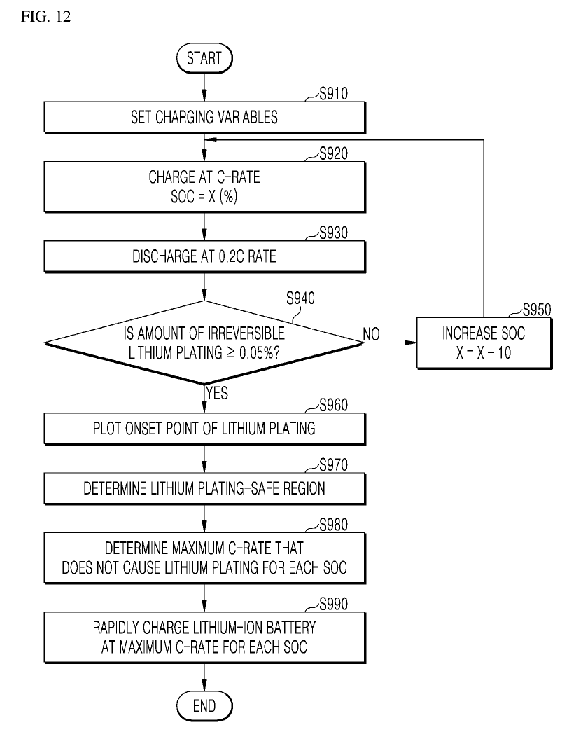

Hereinafter, a rapid charging method for a lithium-ion battery according to one example will be described with reference to FIG. 12, and the rapid charging apparatus 100 for the lithium-ion battery described above with reference to FIG. 2 will be referred to as an example of an apparatus that performs the method.

FIG. 12 is a flowchart illustrating a rapid charging method for a lithium-ion battery according to one example.

In S910, variables that may affect the occurrence of lithium plating during charging of a lithium-ion battery may include operating temperature, charging current, and state of charge. Accordingly, the rapid charging apparatus 100 for a lithium-ion battery may set the operating temperature (T), C-rate (N), and SoC as charging variables of the lithium-ion battery.

Based on the completion of the setting of charging variables of the lithium-ion battery, the rapid charging apparatus 100 for the lithium-ion battery may be configured to repeatedly perform charge-discharge cycles for the lithium-ion battery according to a predetermined C-rate and a predetermined SoC, under constant operating temperature conditions predetermined for analysis of a pouch cell that has completed a formation process.

In one example, a method in which charge-discharge cycles are repeatedly performed for a lithium-ion battery based on the predetermined C-rate and the predetermined SoC value, under constant operating temperature conditions, may be referred to as an SoC sweep method.

That is, the rapid charging apparatus 100 for the lithium-ion battery may be configured to determine an SoC value at which lithium plating begins to occur, based on a Coulombic efficiency determined through an SoC sweep method in which charge-discharge cycles are repeatedly performed based on the predetermined C-rate and the predetermined SoC value under constant operating temperature conditions.

To this end, in S920 to S950, the rapid charging apparatus 100 for the lithium-ion battery may be configured to repeatedly perform charging cycles at a C-rate to be analyzed, under constant operating temperature conditions, while the SoC value for charging is gradually increased in each cycle (e.g., x starts at 10 and increases by 10 per cycle), and discharging in each cycle is performed at a constant C-rate (e.g., 0.2C) that is set lower than the C-rate to be analyzed.

In this process, the rapid charging apparatus 100 for the lithium-ion battery may be configured to set a defined Coulombic efficiency, which is consistently and repeatedly measured during repeated charge-discharge cycles in the SoC sweep method, as a reference Coulombic efficiency, and determine an amount of irreversible lithium plating occurring in each cycle based on a difference between the reference Coulombic efficiency and the Coulombic efficiency measured in each cycle.

The amount of irreversible lithium plating may be determined by multiplying the difference between the reference Coulombic efficiency and the Coulombic efficiency measured in each cycle by the SoC value set in each cycle.

For example, the Coulombic efficiency measured in each cycle maintains a constant value (e.g., 99.4%) and then shows a decreasing trend based on high-rate charging being performed up to a high SoC range. In this case, a consistently and repeatedly measured Coulombic efficiency may be set as a reference Coulombic efficiency, and the amount of irreversible lithium plating may be determined by multiplying the difference between the reference Coulombic efficiency and the Coulombic efficiency measured in each cycle by a charge capacity.

It should be noted that the reference Coulombic efficiency is not 100% because time-dependent side reactions, such as the formation of a solid electrolyte interphase (SEI) layer, inevitably occur inside the cell. This may be confirmed by the fact that the baseline value of the Coulombic efficiency decreases as the operating temperature increases.

In step S960, the rapid charging apparatus 100 for the lithium-ion battery may determine, as an onset point of lithium plating, a point at which the amount of irreversible lithium plating is determined to exceed a specific ratio (e.g., 0.05%), and may complete a 3D contour plot by plotting, on a three-dimensional graph, an SoC value corresponding to the onset point of lithium plating for each operating temperature and C-rate.

The rapid charging apparatus 100 for the lithium-ion battery may plot, on a three-dimensional graph, an SoC value corresponding to an onset point of lithium plating by setting an X-axis to the C-rate, a Y-axis to the operating temperature, and a Z-axis to the SoC.

In steps S970 and S980, based on the completion of the 3D contour plot, the rapid charging apparatus 100 for the lithium-ion battery may be configured to determine a lithium plating-safe region in which the lithium plating does not occur in the completed 3D contour plot, and determine, for each SoC, a maximum C-rate at which the lithium-ion battery may be charged without lithium plating, based on the determined region.

In this case, based on a boundary surface at which lithium plating begins to occur, the rapid charging apparatus 100 for the lithium-ion battery may be configured to determine a region in which the lithium plating does not occur in the completed 3D contour plot.

For example, a 3D contour plot depicts a boundary surface representing the onset of lithium plating, using operating temperature, C-rate, and SoC as charging variables, with SoC set as the Z-axis. A region below the boundary surface may be determined as a lithium plating-safe region in which lithium plating does not occur. Accordingly, this enables implementation of a protocol for determining, for each SoC, a maximum C-rate that does not cause lithium plating.

However, to fully utilize the 3D contour plot in implementing the protocol for determining the maximum C-rate, it may be essential to provide an environment capable of rapidly adjusting not only the C-rate but also the operating temperature for each SoC.

In S990, the rapid charging apparatus 100 for the lithium-ion battery may be configured to rapidly charge the lithium-ion battery at a C-rate that does not exceed the maximum C-rate, based on a determination of the maximum C-rate that does not cause lithium plating for each SoC.

That is, the rapid charging apparatus 100 for the lithium-ion battery may be configured to rapidly charge the lithium-ion battery at the maximum C-rate within the lithium plating-safe region, which is defined based on the boundary surface at which the lithium plating occurs for each SoC in the 3D contour plot.

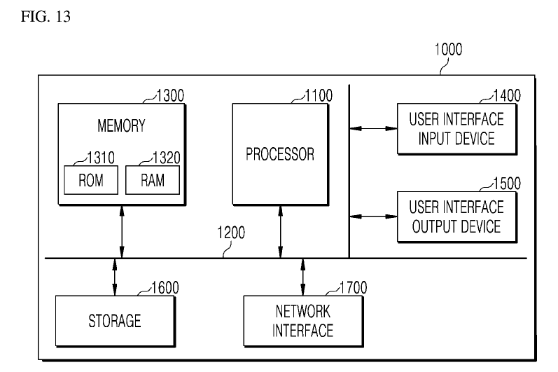

FIG. 13 shows an example computing system (e.g., a computing device for charging a battery, a computing device coupled to a charger or any other apparatus associated with a battery charging system). One or more controllers, processors, etc. described herein, such as one or more components of a computing device for battery charging and any other components and devices disclosed herein, may be implemented by or in the computing system as shown in FIG. 13.

A computing system 1000 may include at least one processor 1100, memory 1300, a user interface input device 1400, a user interface output device 1500, a storage 1600, and a network interface 1700, which are connected with each other via a bus 1200.

The processor 1100 may be a central processing unit (CPU) or a semiconductor device that processes instructions stored in the memory 1300 and/or the storage 1600. Each of the memory 1300 and the storage 1600 may include various types of volatile or nonvolatile storage media. For example, the memory 1300 may include a read-only memory (ROM) and a random-access memory (RAM).

Communication interface(s) (also referred to as communication device(s), communicator(s), communication module(s), communication unit(s), etc.), such as the network interface 1700, may allow software and/or data to be transferred between a device and one or more external devices, and/or between one or more components of a device. Communication interface(s) may include a receiver, a transmitter, a transceiver, a modem, a network interface and/or adapter (such as an Ethernet adapter), a radio transceiver, an antenna, a communication port, a Personal Computer Memory Card International Association (PCMCIA) slot and card, or the like. Software and data transferred via communication interface(s) may be in the form of signals, which may be electronic, electromagnetic, optical, infrared, or other signals capable of being received by communication interface(s). These signals may be provided to communication interface(s) via a communication path of a device, which may be implemented using, for example, wire or cable, fiber optics, a cellular link, a radio frequency (RF) link and/or other communications channels. Communication interface(s) may communicate using one or more communication protocols, such as Ethernet, Wi-Fi, near-field communication (NFC), Infrared Data Association (IrDA), Bluetooth, Bluetooth low energy (BLE), Zigbee, Long-Term Evolution (LTE), 5G New Radio (NR), vehicle-to-everything (V2X), a controller area network (CAN), or a local interconnect network (LIN), etc.

Accordingly, the operations of the method or algorithm described in connection with example embodiment(s) disclosed in the specification may be directly implemented with a hardware module, a software module, or a combination of the hardware module and the software module, which is executed by the processor 1100. The software module may reside on a storage medium (e.g., the memory 1300 and/or the storage 1600) such as RAM, a flash memory, ROM, an erasable and programmable ROM (EPROM), an electrically EPROM (EEPROM), a register, a hard disk drive, a removable disc, or a compact disc-ROM (CD-ROM).

The storage medium may be coupled to the processor 1100. The processor 1100 may read out information from the storage medium and may write information in the storage medium. Alternatively, the storage medium may be integrated with the processor 1100. The processor and storage medium may be implemented with an application specific integrated circuit (ASIC). The ASIC may be provided in a user terminal. Alternatively, the processor and storage medium may be implemented with separate components in the user terminal.

As used in the present disclosure (especially in the appended claims), the terms "a/an" and "the" include both singular and plural references, unless the context clearly states otherwise. Also, it should be understood that any numerical range recited in the present disclosure is intended to include all sub-ranges subsumed therein (unless expressly indicated otherwise) and accordingly, the disclosed numeral ranges include every individual value between the minimum and maximum values of the numeral ranges.

The steps constituting the method according to the present disclosure may be performed in an appropriate order unless a specific order is described or otherwise specified. That is, the present disclosure is not necessarily limited to the order in which the steps are recited. All examples described in the present disclosure or the terms indicative thereof ("for example", "such as") are merely to describe the present disclosure in greater detail. Therefore, it should be understood that the scope of the present disclosure is not limited to the example embodiments described above or by the use of such terms unless limited by the appended claims. Also, it should be apparent to those skilled in the art that various modifications, combinations, and alternations may be made depending on design conditions and factors within the scope of the appended claims or equivalents thereof.

The present disclosure is thus not limited to the examples described above, and rather intended to include the following appended claims, and all modifications, equivalents, and alternatives falling within the spirit and scope of the following claims.

What is claimed is:

1. An apparatus for charging a lithium-ion battery, the apparatus comprising:
a memory storing at least one instruction; and
a processor configured to execute the at least one instruction, wherein the at least one instruction, executed by the processor, is configured to cause the apparatus to:
control at least one sensor associated with the lithium-ion battery to detect charging variables of the lithium-ion battery;
generate a three-dimensional (3D) contour plot that represents a boundary at which lithium plating begins to occur, based on relationships among the charging variables of the lithium-ion battery, wherein the boundary is formed as a boundary surface in the 3D contour plot;
determine, based on the boundary surface represented in the 3D contour plot, a maximum current rate (C-rate) for charging the lithium-ion battery; and
control, based on the maximum C-rate, charging of the lithium-ion battery.

2. The apparatus of claim 1, further comprising a battery charger configured to charge the lithium-ion battery at or below the maximum C-rate.

3. The apparatus of claim 1, wherein the at least one instruction, executed by the processor, is configured to cause the apparatus to set at least one of an operating temperature, a C-rate, or a state of charge (SoC) as the charging variables of the lithium-ion battery.

4. The apparatus of claim 3, wherein the at least one instruction, executed by the processor, is configured to cause the apparatus to determine an SoC value at which the lithium plating begins to occur, based on a Coulombic efficiency determined through an SoC sweep method, and wherein, in the SoC sweep method, charge-discharge cycles are repeatedly performed based on a predetermined C-rate and a predetermined SoC value under constant operating temperature conditions.

5. The apparatus of claim 4, wherein the SoC sweep method is a method in which, under constant operating temperature conditions, charge-discharge cycles are repeatedly performed at a C-rate to be analyzed, while an SoC value for charging is increased in each cycle and discharging in each cycle is performed at a constant C-rate that is set lower than the C-rate to be analyzed.

6. The apparatus of claim 4, wherein the at least one instruction, executed by the processor, is configured to cause the apparatus to set a defined Coulombic efficiency, which is consistently and repeatedly measured during repeated charge-discharge cycles in the SoC sweep method, as a reference Coulombic efficiency, and determine an amount of irreversible lithium plating occurring in each cycle based on a difference between the reference Coulombic efficiency and the Coulombic efficiency measured in each cycle.

7. The apparatus of claim 6, wherein the amount of irreversible lithium plating is determined by multiplying the difference between the reference Coulombic efficiency and the Coulombic efficiency measured in each cycle by the SoC value set in each cycle.

8. The apparatus of claim 6, wherein the at least one instruction, executed by the processor, is configured to cause the apparatus to determine, as an onset point of lithium plating, a point at which the amount of irreversible lithium plating reaches a predetermined ratio, and generate the 3D contour plot by plotting, on a three-dimensional graph, an SoC value corresponding to the onset point of lithium plating for each operating temperature and C-rate.

9. The apparatus of claim 2, wherein the battery charger is configured to charge the lithium-ion battery at the maximum C-rate within a lithium plating-safe region, which is defined based on the boundary surface in the 3D contour plot.

10. A method performed by an apparatus for charging a lithium-ion battery, the method comprising:
detecting, by controlling at least one sensor associated with the lithium-ion battery, charging variables of the lithium-ion battery;
generating a three-dimensional (3D) contour plot that represents a boundary at which lithium plating begins to occur, based on relationships among the charging variables of the lithium-ion battery, wherein the boundary is formed as a boundary surface in the 3D contour plot;
determining, based on the boundary surface represented in the 3D contour plot, a maximum current rate (C-rate) for charging the lithium-ion battery; and
controlling, based on the maximum C-rate, charging of the lithium-ion battery.

11. The method of claim 10, further comprising charging the lithium-ion battery at or below the maximum C-rate.

12. The method of claim 10, wherein the generating the 3D contour plot comprises setting at least one of an operating temperature, a C-rate, or a state of charge (SoC) as the charging variables of the lithium-ion battery.

13. The method of claim 12, wherein the generating the 3D contour plot comprises determining an SoC value at which the lithium plating begins to occur, based on a Coulombic efficiency determined through an SoC sweep method, and wherein, in the SoC sweep method, charge-discharge cycles are repeatedly performed based on a predetermined C-rate and a predetermined SoC value under constant operating temperature conditions.

14. The method of claim 13, wherein the SoC sweep method is a method in which, under constant operating temperature conditions, charge-discharge cycles are repeatedly performed at a C-rate to be analyzed, while an SoC value for charging is increased in each cycle and discharging in each cycle is performed at a constant C-rate that is set lower than the C-rate to be analyzed.

15. The method of claim 13, wherein the generating the 3D contour plot comprises:
setting a defined Coulombic efficiency, which is consistently and repeatedly measured during repeated charge-discharge cycles in the SoC sweep method, as a reference Coulombic efficiency, and
determining an amount of irreversible lithium plating occurring in each cycle based on a difference between the reference Coulombic efficiency and the Coulombic efficiency measured in each cycle.

16. The method of claim 15, wherein the amount of irreversible lithium plating is determined by multiplying the difference between the reference Coulombic efficiency and the Coulombic efficiency measured in each cycle by the SoC value set in each cycle.

17. The method of claim 15, wherein the generating the 3D contour plot comprises determining, as an onset point of lithium plating, a point at which the amount of irreversible lithium plating reaches a predetermined ratio, and completing the 3D contour plot by plotting, on a three-dimensional graph, an SoC value corresponding to the onset point of lithium plating for each operating temperature and C-rate.

18. The method of claim 11, wherein the charging the lithium-ion battery comprises charging the lithium-ion battery at the maximum C-rate within a lithium plating-safe region, which is defined based on the boundary surface in the 3D contour plot.

19. A charging apparatus comprising:
a charger configured to charge a battery;
at least one sensor to detect sensing data associated with charging variables of the battery;
a memory storing at least one instruction; and
a processor configured to execute the at least one instruction, wherein the at least one instruction, executed by the processor, is configured to cause the charging apparatus to:
receive, from the at least one sensor, the sensing data;
generate a three-dimensional (3D) contour plot that represents a boundary associated with electrode degradation, based on relationships among the charging variables of the battery, wherein the boundary is formed as a boundary surface in the 3D contour plot;
determine, based on the boundary surface represented in the 3D contour plot, a maximum current rate (C-rate) for charging the battery; and
control, based on the maximum C-rate, the charger to charge the battery.

20. The charging apparatus of claim 19, wherein the electrode degradation comprises at least one of lithium plating, metal plating, or anode surface deterioration, and
wherein the at least one sensor comprises at least one of a temperature sensor, a state of charge (SoC) sensor, a voltage sensor, or a current sensor.
